(19) United States
(12) Patent Application Publication
(10) Pub. No.: US 2026/0154467 A1
(43) Pub. Date: Jun. 4, 2026

(54) METHOD ANDAPPARATUS FOR PREDICTING REAMING TORQUE IN HORIZONTAL DIRECTIONAL DRILLING, DEVICE AND STORAGE MEDIUM

(71) Applicant: CHINA THREE GORGES CORPORATION, Wuhan, Hubei (CN)

(72) Inventors: Shun DONG, Wuhan, Hubei (CN); Pengbo YANG, Wuhan, Hubei (CN); Dong WEN, Wuhan, Hubei (CN)

(73) Assignee: CHINA THREE GORGES CORPORATION, Wuhan, Hubei (CN)

(21) Appl. No.: 18/725,051

(22) PCT Filed: Jun. 15, 2023
(86) PCT No.: PCT/CN2023/100468

§ 371 Date: Jun. 27, 2024

(30) Foreign Application Priority Data
Jul. 7, 2022 (CN) 202210794589.1

(51) Int. Cl. G06F 30/17

(52) U.S. Cl. CPC G06F 30/17

(57) ABSTRACT

A method and apparatus for predicting reaming torque in horizontal directional drilling are provided. The method includes collecting horizontal directional drilling data and initial reaming torque data corresponding to the horizontal directional drilling data; preprocessing the horizontal directional drilling data to generate multiple reaming torque prediction data elements; determining an average influence parameter of the horizontal directional drilling data influencing on the reaming torque on the basis of the multiple reaming torque prediction data elements; screening the horizontal directional drilling data on the basis of the average influence parameters to obtain different drilling data combinations; generating a linear fitting determination coefficient; and selecting a drilling data combination corresponding to a maximum linear fitting determination coefficient to establish a reaming torque predicting model, and using the reaming torque predicting model to predict horizontal directional drilling reaming torque.

### FIELD OF THE INVENTION

The present invention relates to the technical field of horizontal directional drilling, specifically relates to a method and apparatus for predicting reaming torque in horizontal directional drilling, and a device and storage medium.

### BACKGROUND OF THE INVENTION

As urban environmental protection raises more and more requirements, in view of reducing damage of ground excavation to the environment, as well as negative influence on urban traffic and residents' lives, horizontal directional drilling has gradually become a main technical means for laying down underground pipe networks in urban areas, rivers and lakes, nature reserves and complex strata. In the process of horizontal directional drilling and reaming, the torque acting on the reamer (that is, reaming torque) is not only a reference factor for reasonably designing number of steps for reaming, but also an important basis for model selection of drilling machines.

However, in existing conventional technologies, determining reaming torque in the process of horizontal directional drilling not only needs to consider causation from formations and a type of a reaming bit on the reamer, but also considers influence of construction parameters, resulting in too many factors influencing on the reaming torque; therefore, it is hardly possible to predict the reaming torque, even possible prediction results tend to have a large error and to be worse reliably, so it is difficult to be widely popularized and applied in engineering practice.

### SUMMARY OF THE INVENTION

Therefore, the technical problem to be solved by the present invention lies in overcoming the defect that there are too many factors influencing on reaming torque in the prior art, so it is hardly possible to predict the reaming torque, even possible prediction results tend to have a large error and to be worse reliably, thus it is difficult to be widely popularized and applied in engineering practice, so that the present invention provides a method and apparatus for predicting reaming torque in horizontal directional drilling, and a device and storage medium.

As a first aspect of the present invention, a method for predicting horizontal directional drilling-reaming torque is proposed in the examples according the present invention, comprising the steps of:
collecting horizontal directional drilling data and initial reaming torque data corresponding to the horizontal directional drilling data;
preprocessing the horizontal directional drilling data to generate multiple reaming torque prediction data elements;
determining an average influence parameter of the horizontal directional drilling data influencing on the reaming torque on the basis of multiple reaming torque prediction data elements;
screening the horizontal directional drilling data on the basis of the average influence parameters to obtain different drilling data combinations;
generating a linear fitting determination coefficient on the basis of the different drilling data combinations and the initial reaming torque data;
selecting a drilling data combination corresponding to a maximum linear fitting determination coefficient to establish a reaming torque predicting model, and using the reaming torque predicting model to predict horizontal directional drilling-reaming torque.

The above-mentioned method for predicting horizontal directional drilling-reaming torque uses the reaming torque predicting model to predict the horizontal directional drilling-reaming torque on the basis of the horizontal directional drilling data, so the method can effectively improve the accuracy of predicting reaming torque, and it is simple, convenient and effective to apply the method, so as to provide a data basis for designing number of steps for reaming and model selection of drilling machines.

Optionally, the horizontal directional drilling data comprises dragging-back force data, rotation rate data, dragging-back distance data, drilling angle change data, reamed diameter data, mud pumping volume data and mud funnel viscosity data.

Optionally, the step of preprocessing the horizontal directional drilling data to generate multiple reaming torque prediction data elements comprises:
inputting the horizontal directional drilling data to which a preset value has been added and the horizontal directional drilling data from which a preset value has been removed, into an initial neural network model to generate multiple reaming torque prediction data elements; the multiple reaming torque prediction data elements including a reaming torque prediction data element corresponding to the horizontal directional drilling data to which a preset value has been added and a reaming torque prediction data element corresponding to the horizontal directional drilling data from which a preset value has been removed.

In the above-mentioned method, it is feasible to only collect horizontal directional drilling data for processing data, so the method does not involve cumbersome numerical calculation, and only needs to input relevant parameters to give a value of predicting reaming torque, so it is easy for the majority of engineering practitioners to accept the method.

Optionally, the average influence parameter of the horizontal directional drilling data influencing on the reaming torque comprises an average influence value, and the average influence value is calculated by the following formula,

$$MIV = \frac{{\sum }_{i = 1}^{n} ( A 1 - A 2 )}{n}$$

where MIV represents an average influence value, n represents number of horizontal directional drilling data, A1 represents a reaming torque prediction data element corresponding to the horizontal directional drilling data to which a preset value has been added, A2 represents a reaming torque prediction data element corresponding to the horizontal directional drilling data from which a preset value has been removed.

In the above-mentioned method, the key factors significantly influencing on the reaming torque, that is, horizontal directional drilling data, are screened out from average influence parameters, and this process excludes the secondary factors that have little influence on the reaming torque, so it not only decreases the number of input variables of the prediction model, but also improves its applicability in engineering practice.

Optionally, the step of screening the horizontal directional drilling data on the basis of the average influence parameters to obtain different drilling data combinations comprises:
sequencing the average influence parameters from a large one to a small one, and selecting the horizontal directional drilling data corresponding to the average influence parameters of different preset numbers on the basis of a sequenced result to make an arrangement and combination, so as to generate different drilling data combinations.

Optionally, the step of generating a linear fitting determination coefficient on the basis of the different drilling data combinations and the initial reaming torque data comprises:
establishing a neural network combination model on the basis of the different drilling data combinations, respectively, and using the neural network combination model to generate a reaming torque prediction data element corresponding to the different drilling data combinations;
generating a linear fitting determination coefficient on the basis of the reaming torque prediction data element corresponding to the different drilling data combinations and the initial reaming torque data.

By way of calculating a linear fitting determination coefficient of different drilling data combinations, the above-mentioned method lays a foundation for subsequently selecting an optimal drilling data combination, and further screens the key factors that have a significant influence on the reaming torque, and improves the accuracy of predicting the reaming torque.

Optionally, the step of selecting a drilling data combination corresponding to a maximum linear fitting determination coefficient to establish a reaming torque predicting model, and using the reaming torque predicting model to predict horizontal directional drilling-reaming torque comprises:
selecting a drilling data combination corresponding to a maximum linear fitting determination coefficient as an optimal drilling data combination, and establishing an initial prediction model on the basis of the optimal drilling data combination;
optimizing initial weights and thresholds of the initial prediction model, then assigning optimized initial weights and initial thresholds to the initial prediction model, so as to generate the horizontal directional drilling-reaming torque predicting model;
collecting current horizontal directional drilling data, and inputting the current horizontal directional drilling data into the horizontal directional drilling-reaming torque predicting model so as to generate current reaming torque.

In the above-mentioned method, optimizing weights and thresholds of the initial prediction model enables the accuracy of predicting the reaming torque to improve.

As a second aspect of the present application, an apparatus for predicting horizontal directional drilling-reaming torque is also proposed, comprising:
a collecting module used for collecting horizontal directional drilling data and initial reaming torque data corresponding to the horizontal directional drilling data;
a preprocessing module used for preprocessing the horizontal directional drilling data to generate multiple reaming torque prediction data elements;
a determining module used for determining an average influence parameter of the horizontal directional drilling data influencing on the reaming torque on the basis of the multiple reaming torque prediction data elements;
an arrangement module used for screening the horizontal directional drilling data on the basis of the average influence parameters to obtain different drilling data combinations;
a generating module used for generating a linear fitting determination coefficient on the basis of the different drilling data combinations and the initial reaming torque data;
a predicting module used for selecting a drilling data combination corresponding to a maximum linear fitting determination coefficient to establish a reaming torque predicting model, and using the reaming torque predicting model to predict horizontal directional drilling-reaming torque.

Optionally, the horizontal directional drilling data comprises dragging-back force data, rotation rate data, dragging-back distance data, drilling angle change data, reamed diameter data, mud pumping volume data and mud funnel viscosity data.

Optionally, the preprocessing module comprises: inputting the horizontal directional drilling data to which a preset value has been added and the horizontal directional drilling data from which a preset value has been removed, into an initial neural network model to generate multiple reaming torque prediction data elements; the multiple reaming torque prediction data elements including a reaming torque prediction data element corresponding to the horizontal directional drilling data to which a preset value has been added and a reaming torque prediction data element corresponding to the horizontal directional drilling data from which a preset value has been removed.

Optionally, in determining module, the average influence parameter of the horizontal directional drilling data influencing on the reaming torque comprises an average influence value, and the average influence value is calculated by the following formula,

$$MIV = \frac{{\sum }_{i = 1}^{n} ( A 1 - A 2 )}{n}$$

where MIV represents an average influence value, n represents number of horizontal directional drilling data, A1 represents a reaming torque prediction data element corresponding to the horizontal directional drilling data to which a preset value has been added, A2 represents a reaming torque prediction data element corresponding to the horizontal directional drilling data from which a preset value has been removed.

Optionally, the arrangement module comprises: sequencing the average influence parameters from a large one to a small one, and selecting the horizontal directional drilling data corresponding to the average influence parameters of different preset numbers on the basis of a sequenced result to make an arrangement and combination, so as to generate different drilling data combinations.

Optionally, the generating module comprises: a generating unit used for establishing a neural network combination model on the basis of the different drilling data combinations, respectively; and using the neural network combination model to generate a reaming torque prediction data element corresponding to the different drilling data combinations;
a calculating unit used for generating a linear fitting determination coefficient on the basis of the reaming torque prediction data element corresponding to the different drilling data combinations and the initial reaming torque data.

Optionally, the predicting module comprises: an establishing unit used for selecting a drilling data combination corresponding to a maximum linear fitting determination coefficient as an optimal drilling data combination, and establishing an initial prediction model on the basis of the optimal drilling data combination;
an optimizing unit used for optimizing initial weights and thresholds of the initial prediction model, then assigning optimized initial weights and initial thresholds to the initial prediction model, so as to generate the horizontal directional drilling-reaming torque predicting model;
a predicting unit used for collecting current horizontal directional drilling data, and inputting the current horizontal directional drilling data into the horizontal directional drilling-reaming torque predicting model so as to generate current reaming torque.

As a third aspect of the present application, a computer device of predicting horizontal directional drilling-reaming torque is also proposed. The computer device comprises a processor and a memory, wherein the memory is used for storing a computer program, the computer program includes a program, and the processor is configured to call the computer program to execute the method for the first aspect of the present invention.

As a fourth aspect of the present application, a storage medium of predicting horizontal directional drilling-reaming torque is also proposed. The storage medium stores a computer program, and the computer program is executed by a processor to realize the method for the first aspect of the present invention.

### BRIEF DESCRIPTION OF THE DRAWINGS

To describe the embodiments of the present invention or the technical solutions in the prior art more clearly, the following briefly introduces the accompanying drawings required for describing the embodiments or the descriptions in the prior art. Apparently, the accompanying drawings in the following description show merely some embodiments of the present invention, and a person of ordinary skill in the art may still derive other drawings from these accompanying drawings without creative efforts.

FIG. 1 is a flowchart of the method for predicting horizontal directional drilling-reaming torque in Example 1 of the present invention.

FIG. 2 is a diagram of the method for predicting horizontal directional drilling-reaming torque in Example 1 of the present invention.

FIG. 3 is a flowchart of S105 in Example 1 of the present invention.

FIG. 4 is a flowchart of S106 in Example 1 of the present invention.

FIG. 5 is a comparison diagram between the expected value of the test sample and the test value of the test sample in Example 1 of the present invention.

FIG. 6 is a schematic diagram of the apparatus for predicting horizontal directional drilling-reaming torque in Example 2 of the present invention.

FIG. 7 is a schematic diagram of an instance of the generating module 65 in Example 2 of the present invention.

FIG. 8 is a schematic diagram of the predicting module 66 in Example 2 of the present invention.

### DETAILED DESCRIPTION OF SOME EMBODIMENTS

The technical solutions in the embodiments of the present invention will be clearly and completely described as follows in combination with the drawings in the examples of the present invention, but obviously, the described examples are only a part of the embodiments of the present invention, rather than all the embodiments. Based on the examples of the present invention, all other examples obtained by a person skilled in the art without creative efforts shall fall within the protection scope of the present invention.

In the description of the present invention, it should be explained that the terms such as “center”, “up”, “down”, “left”, “right”, “vertical”, “horizontal”, “inner” and “outer” indicating the directional or positional relations on the basis of the directional or positional relations shown in the drawings are only used for conveniently describing the present invention and simplifying the description, not indicate or imply that the referred devices or elements must have a specific orientation and be configured and operated in a specific direction; therefore, they cannot be construed as a limitation on the present invention.

In addition, the technical features involved in the different embodiments of the present invention described as follows may be combined with each other as long as they do not conflict with each other.

### Example 1

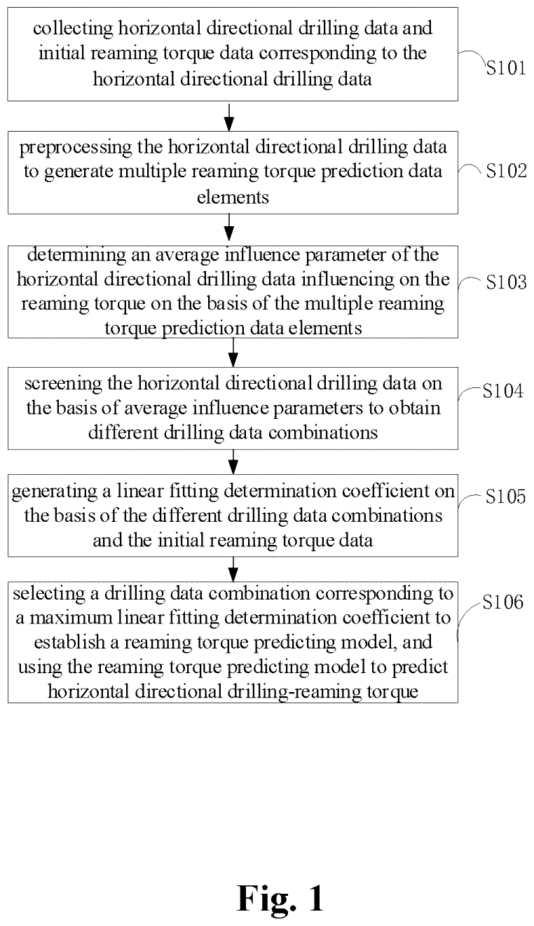

As shown in FIG. 1, the method for predicting horizontal directional drilling-reaming torque provided by this example includes the following steps.

S101 collecting horizontal directional drilling data and initial reaming torque data corresponding to the horizontal directional drilling data.

Wherein, on the basis of an existing large amount of data about projects for horizontally directionally drilling and laying down pipelines, collecting the horizontal directional drilling data, which includes dragging-back force data (unit: kN), rotation rate data (unit: r/pm), dragging-back distance data (unit: m), drilling angle change data (unit: rad), reamed diameter data (unit: mm), mud pumping volume data (unit: L/min) and mud funnel viscosity data (unit: s) as well as the initial reaming torque data corresponding to the above horizontal directional drilling data, that is, reaming torque (unit: kN·m).

Further, performing conversion on the collected horizontal directional drilling data and the initial reaming torque data on the basis of the units of the above physical quantities, then establishing a dataset on the basis of the converted horizontal directional drilling data and initial reaming torque data, next randomly selecting part of the data in the dataset as training samples P, and using the remaining data in the dataset as test samples V.

Further, enabling the number of the training samples to account for about ⅘ of the total of the samples in the dataset, or determining the number by way of generating random integers in the range of (1, the total of the samples in the dataset).

S102 preprocessing the horizontal directional drilling data to generate multiple reaming torque prediction data elements.

Specifically, determining a BP neural network structure (feedforward neural network structure), number of hidden layer neurons, a transfer function and an evaluation function and establishing an initial neural network model, then using the dragging-back force data, the rotation rate data, dragging-back distance data, the drilling angle change data, the reamed diameter data, the mud pumping volume data and the mud funnel viscosity data in the training sample P as input variables, and the initial reaming torque data as output variables, so as to train the initial neural network model.

Wherein, the initial neural network model adopts a three-layer BP neural network structure (that is, an input layer, a hidden layer and an output layer), a hidden layer transfer function adopts a hyperbolic tangent S-shaped function, an output layer transfer function adopts a linear function, and a mean square error is used as a network performance evaluation function, and the number of the hidden layer neurons is calculated by the following formula.

M=2N+1

In the above formula, M represents number of hidden layer neurons, and N represents number of input variables.

Further, inputting the horizontal directional drilling data to which a preset value has been added (referring to the horizontal directional drilling data in the test sample P) and the horizontal directional drilling data from which a preset value has been removed, into an initial neural network model to generate multiple reaming torque prediction data elements; wherein the multiple reaming torque prediction data elements includes a reaming torque prediction data element corresponding to the horizontal directional drilling data to which a preset value has been added and a reaming torque prediction data element corresponding to the horizontal directional drilling data from which a preset value has been removed.

Wherein, the input variable in the training sample P (that is, the horizontal directional drilling data in the test sample P) increases by 10% on the basis of its original value to form a new training sample P1, and decreases by 10% on the basis of its original value to form a new training sample P2, thus P1 and P2 are input into the outputs corresponding to predicting P1 and P2 in the initial neural network model, which are A1 (that is, the reaming torque prediction data element corresponding to the horizontal directional drilling data to which a preset value has been added) and A2 (that is, the reaming torque prediction data element corresponding to the horizontal directional drilling data from which a preset value has been removed), respectively.

S103 determining an average influence parameter of the horizontal directional drilling data influencing on the reaming torque on the basis of the multiple reaming torque prediction data elements.

Wherein, the average influence parameter of the horizontal directional drilling data influencing on the reaming torque includes an average influence value, and the average influence value is calculated by the following formula.

$$MIV = \frac{{\sum }_{i = 1}^{n} ( A 1 - A 2 )}{n}$$

In the above formula, MIV represents an average influence value, n represents number of horizontal directional drilling data (that is, number of training samples), A1 represents a reaming torque prediction data element corresponding to the horizontal directional drilling data to which a preset value has been added, A2 represents a reaming torque prediction data element corresponding to the horizontal directional drilling data from which a preset value has been removed.

S104 screening the horizontal directional drilling data on the basis of average influence parameters to obtain different drilling data combinations.

Wherein, sequencing the average influence parameters (that is, the average influence value corresponding to the horizontal directional drilling data in the test sample P) from a large one to a small one, and selecting the horizontal directional drilling data corresponding to the average influence parameters of different preset numbers (N≥3) on the basis of a sequenced result to make an arrangement and combination, so as to generate different drilling data combinations.

For example, sequencing the horizontal directional drilling data based on the result of sequencing the average influence values among the average influence parameters, and the result is as follows: dragging-back force data, rotation rate data, dragging-back distance data, drilling angle change data, reamed diameter data, mud pumping volume data, mud funnel viscosity data; selecting the top 3 horizontal directional drilling data as a first drilling data combination (dragging-back force data, rotation rate data, dragging-back distance data); selecting the top 4 horizontal directional drilling data as a second drilling data combination (dragging-back force data, rotation rate data, dragging-back distance data, drilling angle change data); selecting the top 5 horizontal directional drilling data as a third drilling data combination (dragging-back force data, rotation rate data, dragging-back distance data, drilling angle change data, reamed diameter data); selecting the top 6 horizontal directional drilling data as a fourth drilling data combination (dragging-back force data, rotation rate data, dragging-back distance data, drilling angle change data, reamed diameter data, mud pumping volume data); selecting the top 7 horizontal directional drilling data as a fifth drilling data combination (dragging-back force data, rotation rate data, dragging-back distance data, drilling angle change data, reamed diameter data, mud pumping volume data, mud funnel viscosity data); then, generating five sets of drilling data combinations, that is (dragging-back force data, rotation rate data, dragging-back distance data), (dragging-back force data, rotation rate data, dragging-back distance data, drilling angle change data), (dragging-back force data, rotation rate data, dragging-back distance data, drilling angle change data, reamed diameter data), (dragging-back force data, rotation rate data, dragging-back distance data, drilling angle change data, reamed diameter data, mud pumping volume data), (dragging-back force data, rotation rate data, dragging-back distance data, drilling angle change data, reamed diameter data, mud pumping volume data, mud funnel viscosity data).

S105 generating a linear fitting determination coefficient on the basis of the different drilling data combinations and the initial reaming torque data.

S106 selecting a drilling data combination corresponding to a maximum linear fitting determination coefficient to establish a reaming torque predicting model, and using the reaming torque predicting model to predict horizontal directional drilling-reaming torque.

The above-mentioned method for predicting horizontal directional drilling-reaming torque uses the reaming torque predicting model to predict the horizontal directional drilling-reaming torque on the basis of the horizontal directional drilling data, so the method can effectively improve the accuracy of predicting reaming torque, and it is simple, convenient and effective to apply the method, so as to provide a data basis for designing number of steps for reaming and model selection of drilling machines.

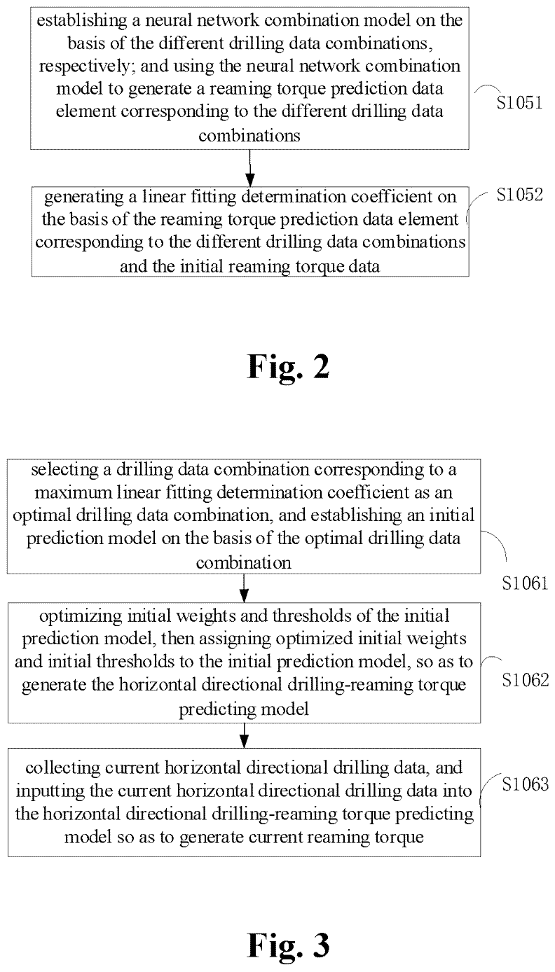

Preferably, as shown in FIG. 2, S105 generating a linear fitting determination coefficient on the basis of the different drilling data combinations and the initial reaming torque data includes the following sub-steps.

S1051 establishing a neural network combination model on the basis of the different drilling data combinations, respectively; and using the neural network combination model to generate a reaming torque prediction data element corresponding to the different drilling data combinations.

Specifically, establishing the neural network combination models corresponding to the different drilling data combinations, respectively, wherein the BP neural network structure, the number of hidden layer neurons, the transfer function, the evaluation function and the output variables are the same as those of the initial neural network model, and the input variables are different drilling data combinations; using the data in the training sample P to train the combined neural network mode to generate a trained neural network combination model.

Furthermore, making an arrangement and combination on the horizontal directional drilling data in the test sample V according to the different drilling data combinations, and inputting the horizontal directional drilling data on which the arrangement and combination has been made, into the trained neural network combination model to generate the reaming torque prediction data element corresponding to the different drilling data combinations.

S1052 generating a linear fitting determination coefficient on the basis of the reaming torque prediction data element corresponding to the different drilling data combinations and the initial reaming torque data.

Wherein, the linear fitting determination coefficient is calculated by the following formula.

$${R}^{2} = \frac{{\sum }_{i = 1}^{m} {( {y}_{i} - \frac{1}{m} {\sum }_{i = 1}^{m} {a}_{i} )}^{2}}{{\sum }_{i = 1}^{m} {( {a}_{i} - \frac{1}{m} {\sum }_{i = 1}^{m} {a}_{i} )}^{2}}$$

In the above formula, R² represents a linear fitting determination coefficient, m represents number of test samples, aᵢ represents an expected output of the i^{th} test sample (that is, initial reaming torque data in the test sample), yᵢ represents a predicted BP neural network output of the i^{th} test sample (that is, reaming torque prediction data element).

Preferably, as shown in FIG. 3, S106 selecting the drilling data combination corresponding to the maximum linear fitting determination coefficient to establish a reaming torque predicting model, and using the reaming torque predicting model to predict the horizontal directional drilling-reaming torque includes the following sub-steps.

S1061 selecting a drilling data combination corresponding to a maximum linear fitting determination coefficient as an optimal drilling data combination, and establishing an initial prediction model on the basis of the optimal drilling data combination.

Specifically, establishing an initial prediction model on the basis of the optimal drilling data combination, wherein the BP neural network structure, the number of hidden layer neurons, the transfer function, the evaluation function and the output variables are the same as those of the initial neural network model, and the input variable is the optimal drilling data combination; using the data in the training sample P to train the initial prediction model to generate a trained initial prediction model.

Alternatively, retrieving the neural network combination model corresponding to the optimal drilling data combination as a trained initial prediction model.

S1062 optimizing initial weights and thresholds of the initial prediction model, then assigning optimized initial weights and initial thresholds to the initial prediction model, so as to generate the horizontal directional drilling-reaming torque predicting model.

Specifically, determining initial parameters of a genetic algorithm, that is, setting an initial population size as 20, setting a population evolutionary generation number as 50, setting a crossover probability as 0.6, setting a mutation probability as 0.1, setting an initial weight range as (−3,3), and setting an initial threshold range as (−3,3); optimizing the initial weights and thresholds of the initial prediction model through the genetic algorithm.

Wherein, the step of optimizing the initial weights and thresholds of the initial prediction model through the genetic algorithm includes the following sub-steps.

(1) Population initialization: randomly generating a W-size initial population, in which each individual contains a set of weights and thresholds of the BP neural network.

(2) Individual coding: adopting a real number coding method to encode an individual into a real number string.

(3) Individual-fitness calculation: obtaining the weights and thresholds of the BP neural network after individual decoding, and training the BP neural network through the training sample P; obtaining a predicted output of the training sample P through the trained BP neural network, and taking a reciprocal of a squared error sum between the predicted output and an expected output of the training sample P as an individual fitness value F, which is calculated by the following formula.

$$F = \frac{1}{{{\sum }_{i = 1}}^{n} {( {y}_{i} - {a}_{i} )}^{2}}$$

In the formula, n represents number of training samples, aᵢ represents an expected output of the i^{th} test sample, yᵢ represents a predicted BP neural network output of the i^{th} test sample.

(4) Choice operation: using a proportional choice operator to calculate a probability that an individual is chosen; the probability Pᵢ that an individual i is chosen is as follows.

$${P}_{i} = \frac{{F}_{i}}{{{\sum }_{i = 1}}^{W} {F}_{i}}$$

In the formula, W represents number of individuals in a population; Fᵢ represents a fitness value of an individual i.

(5) Crossover operation: crossing an individual x with an individual y at a position j; a j-position gene at which they have been crossed with each other is calculated as the following formulas.

$${a}_{xi} = {a}_{xj} ( 1 - b ) + {a}_{yj} b$$

$${a}_{yj} = {a}_{yj} ( 1 - b ) + {a}_{xj} b$$

In the formulas, aₓⱼ represents a j-position gene at which an individual x has been crossed, a_{yj} represents a j-position gene at which an individual y has been crossed, b represents a random number in a range [0,1].

(6) Mutation operation: selecting a j-position gene of an individual x for mutation operation; the mutated j-position gene is as follows.

$${a}_{xj} = \{ \begin{matrix}{a}_{xj} + ( {a}_{xj} - {a}_{max} ) \cdot f ( g ) & r \leq 0.5 \\ {a}_{xj} + ( {a}_{xj} - {a}_{min} ) \cdot f ( g ) & r \geq 0.5\end{matrix}$$

$$f ( g ) = \frac{1}{{( 1 - g / {G}_{max} )}^{2}}$$

In the formulas, aₘₐₓ represents an upper limit of a j-position gene, aₘᵢₙ represents a lower limit of a j-position gene, g represents current number of iterations, Gₘₐₓ represents maximum number of iterations, r represents a random number in a range [0,1].

(7) Obtaining an optimal individual through the above steps (1)-(6), that is, an optimal initial weight and an optimal initial threshold of the BP neural network.

S1063 collecting current horizontal directional drilling data, and inputting the current horizontal directional drilling data into the horizontal directional drilling-reaming torque predicting model so as to generate current reaming torque.

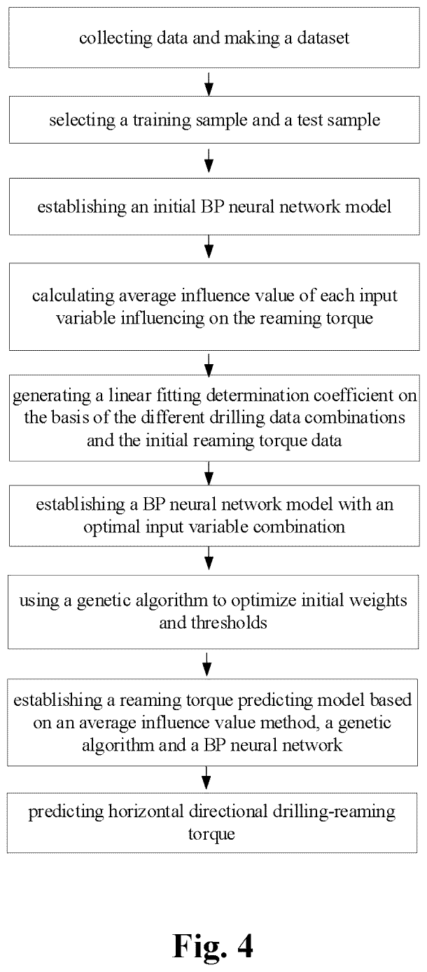

As shown in FIG. 4, we shall describe the method for predicting horizontal directional drilling-reaming torque by way of providing a instance, and its specific steps are as follows.

S1: Collecting 84 sets of relevant data on the basis of the existing construction data about projects for horizontally directionally drilling and laying down pipelines, and performing conversion on their units, then establishing the reaming torque dataset shown in Table 1 as follows.

TABLE 1

| | dragging- | | dragging- | drilling | | mud | mud | initial |
|---|---|---|---|---|---|---|---|---|
| | back | rotation | back | angle | reamed | pumping | funnel | reaming |
| | force | rate | distance | change | diameter | volume | viscosity | torque |
| | data | data | data | data | data | data | data | data |
| sample | (10 kN) | (r/min) | (m) | (rad) | (mm) | (L/min) | (s) | (kN · m) |
| 1 | 11.5 | 15 | 146.0 | 1.2 | 559 | 3400 | 62 | 13.0 |
| 2 | 12 | 15 | 251.3 | 2.4 | 559 | 3400 | 65 | 16.5 |
| 3 | 10.5 | 15 | 279.9 | 2.5 | 559 | 3400 | 66 | 16.0 |
| 4 | 8.5 | 18 | 260.8 | 2.4 | 762 | 3400 | 64 | 15.5 |
| 5 | 11.5 | 18 | 316.8 | 2.8 | 762 | 3400 | 64 | 24.5 |
| 6 | 12 | 18 | 345.5 | 2.9 | 762 | 3400 | 65 | 19.0 |
| 7 | 8 | 15 | 201.3 | 1.7 | 559 | 2260 | 53 | 9.5 |
| 8 | 13 | 15 | 287.1 | 2.3 | 559 | 2260 | 53 | 10.5 |
| 9 | 14 | 15 | 258.4 | 2.1 | 559 | 2260 | 61 | 10.0 |
| 10 | 8.5 | 15 | 230.1 | 1.9 | 762 | 3400 | 51 | 11.0 |
| 11 | 10 | 15 | 296.7 | 2.4 | 762 | 3400 | 52 | 15.0 |
| 12 | 10 | 15 | 325.0 | 2.8 | 762 | 3400 | 61 | 12.0 |
| 13 | 7.5 | 15 | 220.5 | 1.9 | 914 | 3400 | 52 | 19.0 |
| 14 | 5 | 15 | 258.4 | 2.1 | 914 | 3400 | 53 | 15.5 |
| 15 | 8 | 15 | 239.8 | 2.0 | 914 | 3400 | 52 | 19.0 |
| 16 | 15 | 35 | 219.9 | 1.4 | 559 | 2260 | 65 | 25.0 |
| 17 | 19 | 33 | 335.8 | 2.1 | 559 | 2260 | 65 | 26.0 |
| 18 | 18 | 33 | 306.9 | 1.9 | 559 | 2260 | 64 | 26.0 |
| 19 | 14 | 28 | 181.3 | 1.2 | 813 | 3400 | 60 | 32.0 |
| 20 | 16 | 30 | 316.5 | 1.9 | 813 | 3400 | 61 | 33.0 |
| 21 | 15 | 32 | 287.5 | 1.9 | 813 | 3400 | 57 | 32.0 |
| 22 | 14 | 30 | 233.3 | 2.1 | 559 | 4000 | 75 | 25.0 |
| 23 | 18 | 30 | 337.9 | 2.8 | 559 | 4000 | 80 | 30.0 |
| 24 | 15 | 30 | 280.4 | 2.5 | 559 | 4000 | 79 | 27.0 |
| 25 | 10 | 30 | 337.9 | 2.8 | 762 | 4000 | 82 | 20.0 |
| 26 | 10 | 30 | 271.6 | 2.4 | 762 | 4000 | 82 | 19.0 |
| 27 | 10 | 30 | 309.4 | 2.7 | 762 | 4000 | 80 | 20.0 |
| 28 | 10 | 30 | 337.9 | 2.8 | 914 | 4000 | 80 | 23.0 |
| 29 | 10 | 30 | 424.4 | 3.3 | 914 | 4000 | 83 | 23.0 |
| 30 | 10 | 30 | 481.3 | 3.5 | 914 | 4000 | 79 | 23.0 |
| 31 | 9 | 15 | 175.9 | 2.0 | 508 | 2260 | 43 | 17.5 |
| 32 | 9 | 15 | 193.8 | 2.1 | 508 | 2260 | 48 | 11.0 |
| 33 | 9 | 15 | 213.1 | 2.2 | 508 | 2260 | 46 | 13.0 |
| 34 | 18.5 | 15 | 166.2 | 1.9 | 660 | 2260 | 42 | 17.0 |
| 35 | 19 | 15 | 241.4 | 2.4 | 660 | 2260 | 45 | 20.0 |
| 36 | 12.5 | 15 | 222.8 | 2.2 | 660 | 2260 | 45 | 20.0 |
| 37 | 10.5 | 15 | 232.4 | 2.2 | 813 | 2260 | 45 | 18.0 |
| 38 | 11 | 18 | 193.8 | 2.1 | 813 | 2260 | 47 | 20.0 |
| 39 | 10.5 | 15 | 259.8 | 2.4 | 813 | 2260 | 45 | 17.5 |
| 40 | 13 | 15 | 193.8 | 2.1 | 965 | 2260 | 43 | 19.0 |
| 41 | 16 | 15 | 222.8 | 2.2 | 965 | 2260 | 43 | 20.0 |
| 42 | 15.5 | 15 | 232.4 | 2.2 | 965 | 2260 | 44 | 20.0 |
| 43 | 20 | 45 | 365.3 | 2.8 | 457 | 1500 | 69 | 20.0 |
| 44 | 20 | 45 | 413.0 | 3.0 | 457 | 1500 | 72 | 20.0 |
| 45 | 20 | 45 | 432.2 | 3.0 | 457 | 1500 | 74 | 20.0 |
| 46 | 17.5 | 45 | 403.5 | 3.0 | 610 | 1500 | 72 | 20.0 |
| 47 | 20 | 45 | 537.5 | 3.3 | 610 | 1500 | 69 | 26.0 |
| 48 | 20 | 45 | 556.6 | 3.4 | 610 | 1500 | 70 | 24.0 |
| 49 | 17 | 45 | 394.0 | 2.9 | 813 | 1500 | 72 | 26.0 |
| 50 | 17.5 | 45 | 547.1 | 3.4 | 813 | 1500 | 76 | 20.0 |
| 51 | 17.5 | 45 | 527.8 | 3.3 | 813 | 1500 | 74 | 20.0 |
| 52 | 10 | 40 | 384.4 | 2.9 | 965 | 2000 | 76 | 34.0 |
| 53 | 10 | 40 | 537.5 | 3.3 | 965 | 2000 | 75 | 36.0 |
| 54 | 10 | 40 | 480.0 | 3.1 | 965 | 2000 | 75 | 36.0 |
| 55 | 15 | 40 | 384.4 | 2.9 | 1118 | 2000 | 75 | 40.0 |
| 56 | 15 | 40 | 489.5 | 3.1 | 1118 | 2000 | 80 | 40.0 |
| 57 | 15 | 40 | 537.5 | 3.0 | 1118 | 2000 | 80 | 40.0 |
| 58 | 2 | 45 | 164.7 | 1.5 | 559 | 1500 | 88 | 6.0 |
| 59 | 2.5 | 40 | 183.8 | 1.7 | 559 | 1000 | 88 | 6.0 |
| 60 | 2.5 | 40 | 212.6 | 1.9 | 559 | 1000 | 88 | 6.0 |
| 61 | 2 | 40 | 174.2 | 1.6 | 762 | 600 | 88 | 4.0 |
| 62 | 10 | 45 | 116.7 | 1.1 | 914 | 1500 | 86 | 10.0 |
| 63 | 5 | 30 | 183.8 | 1.7 | 914 | 500 | 86 | 10.0 |
| 64 | 5 | 25 | 222.3 | 2.0 | 914 | 500 | 86 | 10.0 |
| 65 | 20 | 50 | 183.8 | 2.3 | 559 | 600 | 43 | 14.0 |
| 66 | 20 | 50 | 212.9 | 2.5 | 559 | 500 | 42 | 14.0 |
| 67 | 15 | 50 | 174.2 | 2.2 | 762 | 600 | 45 | 18.0 |
| 68 | 18 | 50 | 203.2 | 2.4 | 762 | 600 | 45 | 18.0 |
| 69 | 22 | 50 | 231.5 | 2.6 | 762 | 600 | 43 | 22.0 |
| 70 | 18 | 45 | 193.5 | 2.3 | 965 | 600 | 43 | 20.0 |
| 71 | 20 | 45 | 222.6 | 2.6 | 965 | 600 | 43 | 18.0 |
| 72 | 24 | 45 | 231.5 | 2.6 | 965 | 600 | 43 | 18.0 |
| 73 | 28 | 40 | 433.0 | 2.2 | 559 | 2000 | 66 | 22.5 |
| 74 | 26.5 | 40 | 452.1 | 2.3 | 559 | 1600 | 62 | 32.5 |
| 75 | 30.5 | 40 | 499.1 | 2.6 | 559 | 1500 | 62 | 21.0 |
| 76 | 17 | 40 | 442.5 | 2.2 | 762 | 2000 | 66 | 26.5 |
| 77 | 10.5 | 40 | 471.1 | 2.4 | 762 | 2000 | 66 | 23.0 |
| 78 | 11.5 | 40 | 509.6 | 2.7 | 762 | 2000 | 66 | 27.0 |
| 79 | 12.5 | 40 | 519.1 | 2.7 | 965 | 2000 | 65 | 29.0 |
| 80 | 19.5 | 40 | 538.2 | 2.8 | 965 | 2000 | 61 | 29.0 |
| 81 | 23.5 | 40 | 557.3 | 2.9 | 965 | 2000 | 61 | 29.0 |
| 82 | 17 | 40 | 490.5 | 2.5 | 1118 | 2000 | 64 | 29.0 |
| 83 | 13.5 | 40 | 566.8 | 3.0 | 1118 | 2000 | 65 | 28.0 |
| 84 | 14.5 | 40 | 586.1 | 3.1 | 1118 | 2000 | 63 | 27.0 |

S2: Determining a training sample P by randomly generating 68 integers in the range of (1,84) (as shown in Table 2), and using the remaining 16 sets of data as a test sample V.

TABLE 2

| | dragging- | | dragging- | drilling | | mud | mud | initial |
|---|---|---|---|---|---|---|---|---|
| | back | rotation | back | angle | reamed | pumping | funnel | reaming |
| | force | rate | distance | change | diameter | volume | viscosity | torque |
| | data | data | data | data | data | data | data | data |
| sample | (10 kN) | (r/min) | (m) | (rad) | (mm) | (L/min) | (s) | (kN · m) |
| 1 | 20 | 45 | 556.6 | 3.4 | 610 | 1500 | 70 | 24.0 |
| 2 | 5 | 30 | 183.8 | 1.7 | 914 | 500 | 86 | 10.0 |
| 3 | 11.5 | 15 | 146.0 | 1.2 | 559 | 3400 | 62 | 13.0 |
| 4 | 10 | 30 | 481.3 | 3.5 | 914 | 4000 | 79 | 23.0 |
| 5 | 18.5 | 15 | 166.2 | 1.9 | 660 | 2260 | 42 | 17.0 |
| 6 | 10.5 | 15 | 279.9 | 2.5 | 559 | 3400 | 66 | 16.0 |
| 7 | 5 | 15 | 258.4 | 2.1 | 914 | 3400 | 53 | 15.5 |
| 8 | 12 | 18 | 345.5 | 2.9 | 762 | 3400 | 65 | 19.0 |
| 9 | 12 | 15 | 251.3 | 2.4 | 559 | 3400 | 65 | 16.5 |
| 10 | 9 | 15 | 175.9 | 2.0 | 508 | 2260 | 43 | 17.5 |
| 11 | 10 | 15 | 296.7 | 2.4 | 762 | 3400 | 52 | 15.0 |
| 12 | 7.5 | 15 | 220.5 | 1.9 | 914 | 3400 | 52 | 19.0 |
| 13 | 18 | 30 | 337.9 | 2.8 | 559 | 4000 | 80 | 30.0 |
| 14 | 15 | 40 | 384.4 | 2.9 | 1118 | 2000 | 75 | 40.0 |
| 15 | 10.5 | 40 | 471.1 | 2.4 | 762 | 2000 | 66 | 23.0 |
| 16 | 15 | 35 | 219.9 | 1.4 | 559 | 2260 | 65 | 25.0 |
| 17 | 17 | 45 | 394.0 | 2.9 | 813 | 1500 | 72 | 26.0 |
| 18 | 18 | 33 | 306.9 | 1.9 | 559 | 2260 | 64 | 26.0 |
| 19 | 18 | 45 | 193.5 | 2.3 | 965 | 600 | 43 | 20.0 |
| 20 | 16 | 30 | 316.5 | 1.9 | 813 | 3400 | 61 | 33.0 |
| 21 | 15 | 32 | 287.5 | 1.9 | 813 | 3400 | 57 | 32.0 |
| 22 | 20 | 50 | 183.8 | 2.3 | 559 | 600 | 43 | 14.0 |
| 23 | 8.5 | 18 | 260.8 | 2.4 | 762 | 3400 | 64 | 15.5 |
| 24 | 15 | 30 | 280.4 | 2.5 | 559 | 4000 | 79 | 27.0 |
| 25 | 9 | 15 | 193.8 | 2.1 | 508 | 2260 | 48 | 11.0 |
| 26 | 10 | 30 | 271.6 | 2.4 | 762 | 4000 | 82 | 19.0 |
| 27 | 14.5 | 40 | 586.1 | 3.1 | 1118 | 2000 | 63 | 27.0 |
| 28 | 10 | 30 | 424.4 | 3.3 | 914 | 4000 | 83 | 23.0 |
| 29 | 20 | 45 | 413.0 | 3.0 | 457 | 1500 | 72 | 20.0 |
| 30 | 10 | 30 | 337.9 | 2.8 | 762 | 4000 | 82 | 20.0 |
| 31 | 9 | 15 | 213.1 | 2.2 | 508 | 2260 | 46 | 13.0 |
| 32 | 20 | 45 | 537.5 | 3.3 | 610 | 1500 | 69 | 26.0 |
| 33 | 13 | 15 | 193.8 | 2.1 | 965 | 2260 | 43 | 19.0 |
| 34 | 14 | 15 | 258.4 | 2.1 | 559 | 2260 | 61 | 10.0 |
| 35 | 20 | 45 | 365.3 | 2.8 | 457 | 1500 | 69 | 20.0 |
| 36 | 10 | 40 | 537.5 | 3.3 | 965 | 2000 | 75 | 36.0 |
| 37 | 8.5 | 15 | 230.1 | 1.9 | 762 | 3400 | 51 | 11.0 |
| 38 | 17.5 | 45 | 403.5 | 3.0 | 610 | 1500 | 72 | 20.0 |
| 39 | 2.5 | 40 | 212.6 | 1.9 | 559 | 1000 | 88 | 6.0 |
| 40 | 24 | 45 | 231.5 | 2.6 | 965 | 600 | 43 | 18.0 |
| 41 | 12.5 | 15 | 222.8 | 2.2 | 660 | 2260 | 45 | 20.0 |
| 42 | 17.5 | 45 | 547.1 | 3.4 | 813 | 1500 | 76 | 20.0 |
| 43 | 22 | 50 | 231.5 | 2.6 | 762 | 600 | 43 | 22.0 |
| 44 | 10 | 40 | 480.0 | 3.1 | 965 | 2000 | 75 | 36.0 |
| 45 | 19.5 | 40 | 538.2 | 2.8 | 965 | 2000 | 61 | 29.0 |
| 46 | 15 | 40 | 489.5 | 3.1 | 1118 | 2000 | 80 | 40.0 |
| 47 | 15 | 40 | 537.5 | 3.0 | 1118 | 2000 | 80 | 40.0 |
| 48 | 11.5 | 18 | 316.8 | 2.8 | 762 | 3400 | 64 | 24.5 |
| 49 | 2.5 | 40 | 183.8 | 1.7 | 559 | 1000 | 88 | 6.0 |
| 50 | 16 | 15 | 222.8 | 2.2 | 965 | 2260 | 43 | 20.0 |
| 51 | 2 | 40 | 174.2 | 1.6 | 762 | 600 | 88 | 4.0 |
| 52 | 26.5 | 40 | 452.1 | 2.3 | 559 | 1600 | 62 | 32.5 |
| 53 | 11 | 18 | 193.8 | 2.1 | 813 | 2260 | 47 | 20.0 |
| 54 | 20 | 50 | 212.9 | 2.5 | 559 | 500 | 42 | 14.0 |
| 55 | 20 | 45 | 432.2 | 3.0 | 457 | 1500 | 74 | 20.0 |
| 56 | 12.5 | 40 | 519.1 | 2.7 | 965 | 2000 | 65 | 29.0 |
| 57 | 17.5 | 45 | 527.8 | 3.3 | 813 | 1500 | 74 | 20.0 |
| 58 | 20 | 45 | 222.6 | 2.6 | 965 | 600 | 43 | 18.0 |
| 59 | 10 | 30 | 309.4 | 2.7 | 762 | 4000 | 80 | 20.0 |
| 60 | 28 | 40 | 433.0 | 2.2 | 559 | 2000 | 66 | 22.5 |
| 61 | 14 | 30 | 233.3 | 2.1 | 559 | 4000 | 75 | 25.0 |
| 62 | 30.5 | 40 | 499.1 | 2.6 | 559 | 1500 | 62 | 21.0 |
| 63 | 2 | 45 | 164.7 | 1.5 | 559 | 1500 | 88 | 6.0 |
| 64 | 11.5 | 40 | 509.6 | 2.7 | 762 | 2000 | 66 | 27.0 |
| 65 | 19 | 33 | 335.8 | 2.1 | 559 | 2260 | 65 | 26.0 |
| 66 | 14 | 28 | 181.3 | 1.2 | 813 | 3400 | 60 | 32.0 |
| 67 | 13.5 | 40 | 566.8 | 3.0 | 1118 | 2000 | 65 | 28.0 |
| 68 | 15 | 50 | 174.2 | 2.2 | 762 | 600 | 45 | 18.0 |

S3: Selecting a three-layer BP neural network structure, wherein the number of hidden layer neurons is 15, a hidden layer transfer function adopts a hyperbolic tangent S-shaped function, an output layer transfer function adopts a linear function, and a mean square error is used as a network performance evaluation function; then using the dragging-back force data, the rotation rate data, dragging-back distance data, the drilling angle change data, the reamed diameter data, the mud pumping volume data and the mud funnel viscosity data as an input variable, and the initial reaming torque data as an output variable, so as to establish an initial BP neural network model, and training the model trough the training sample P in Table 2.

S4: Making the input variable in the training sample P increase by 10% and decrease by 10% on the basis of its original value, respectively, so as to form a new training sample P1 and a new training sample P2, using the initial BP neural network in S3 to predict the outputs corresponding to P1 and P2, which are A1 and A2, respectively, wherein a difference value between A1 and A2 is an influence value generated for the output variable (reaming torque) after having changing the input variable; calculating an average influence value in an average influence parameter of each input variable in proper order, and sequencing them in line of the sizes of the average influence values, which are calculated as follows:

$$MIV = \frac{{{\sum }^{n}}_{i = 1} ( A 1 - A 2 )}{n}$$

In the formula, MIV represents an average influence value of each input variable, and n represents number of training samples.

The calculated average influence values are shown in Table 3 as follows.

TABLE 3

| | dragging- | | dragging- | drilling | | mud | mud |
|---|---|---|---|---|---|---|---|
| | back | rotation | back | angle | reamed | pumping | funnel |
| input | force | rate | distance | change | diameter | volume | viscosity |
| variable | data | data | data | data | data | data | data |
| average | 1.956 | 1.627 | 1.134 | −0.348 | 2.255 | 0.696 | −0.578 |
| influence | | | | | | | |
| value | | | | | | | |

S5: Sequencing different input drilling data combinations in line of the sizes of the average influence parameters of each input variable, as shown in Table 4 as follows.

TABLE 4

| number of input | |
|---|---|
| variables | input variables |
| 3 | reamed diameter data, dragging-back force data, |
| | rotation rate data |
| 4 | reamed diameter data, dragging-back force data, |
| | rotation rate data, dragging-back distance data |
| 5 | reamed diameter data, dragging-back force data, |
| | rotation rate data, dragging-back distance data, |
| | mud pumping volume data |
| 6 | reamed diameter data, dragging-back force data, |
| | rotation rate data, dragging-back distance data, |
| | mud pumping volume data, mud funnel viscosity data |
| 7 | reamed diameter data, dragging-back force data, |
| | rotation rate data, dragging-back distance data, |
| | mud pumping volume data, mud funnel viscosity |
| | data, drilling angle change data |

Establishing the BP neural network model by way of inputting the above different input drilling data combinations respectively (the output variables and other network parameters are consistent with those in S3); training the BP neural network model into which different input drilling data combinations have been input through the training sample P, and calculating a linear fitting determination coefficient between a BP neural network output and an expected output of the test sample V by the following formula:

$${R}^{2} = \frac{{\sum }_{i = 1}^{m} {( {y}_{i} - \frac{1}{m} {\sum }_{i = 1}^{m} {a}_{i} )}^{2}}{{\sum }_{i = 1}^{m} {( {a}_{i} - \frac{1}{m} {\sum }_{i = 1}^{m} {a}_{i} )}^{2}}$$

In the above formula, R² represents a linear fitting determination coefficient, m represents number of test samples, aᵢ represents an expected output of the i^{th} test sample, yᵢ represents a predicted BP neural network output of the i^{th} test sample.

The linear fitting determination coefficients calculated on the basis of the above equation are shown in Table 5 as follows.

TABLE 5

| number of | | | | | |
|---|---|---|---|---|---|
| input variables | 3 | 4 | 5 | 6 | 7 |
| R² | 0.12 | 0.93 | 0.92 | 0.86 | 0.76 |

S6: When the linear fitting determination coefficients has a maximum (R²=0.93) in S5, determining the corresponding input drilling data combination which includes reamed diameter data, dragging-back force data, rotation rate data and dragging-back distance data; using reamed diameter data, dragging-back force data, rotation rate data and dragging-back distance data as input variables, and setting number of hidden layer neurons as 9, then establishing the BP neural network model (the output variables and other network parameters are consistent with S3), and training it though the training sample P in Table 2.

S7: Setting an initial population size as 20, setting a population evolutionary generation number as 50, setting a crossover probability as 0.6, setting a mutation probability as 0.1, setting an initial weight range as (−3,3), and setting an initial threshold range as (−3,3); optimizing the initial weights and thresholds of the initial prediction model in S6 through the genetic algorithm. Table 6 shows the weights from optimized the input layer to the hidden layer.

| | input variable | | | |
|---|---|---|---|---|
| | reamed | dragging- | | dragging- |
| hidden | diameter | back | rotation | back |
| layer neuron | data | force data | rate data | distance data |
| 1 | −2.5019 | 1.5599 | 0.982 | −0.9479 |
| 2 | −1.6842 | 0.1049 | 0.7561 | 0.7135 |
| 3 | −1.7226 | −1.2789 | −0.2508 | 2.0108 |
| 4 | 1.8705 | −0.9818 | 2.3807 | −2.9393 |
| 5 | 1.2964 | 2.2937 | −2.4623 | −0.7481 |
| 6 | 0.4879 | −1.83 | −0.9714 | −1.5261 |
| 7 | −1.2922 | −1.319 | 2.1622 | 2.6025 |
| 8 | 1.9571 | −2.0382 | 1.258 | −1.4142 |
| 9 | −0.5721 | 1.8313 | −2.0298 | −0.9134 |

Table 7 shows the weights optimized from the hidden layer to the output layer.

TABLE 7

| | hidden layer neuron | | | | | | | | |
|---|---|---|---|---|---|---|---|---|---|
| | 1 | 2 | 3 | 4 | 5 | 6 | 7 | 8 | 9 |
| weight | −0.7439 | 0.7711 | −0.9963 | 1.2824 | −0.3666 | −0.7569 | 2.2969 | 1.2525 | 0.4308 |

Table 8 shows the thresholds optimized for the hidden layer and the output layer.

TABLE 8

| | hidden layer neuron | | | | | | | | |
|---|---|---|---|---|---|---|---|---|---|
| | 1 | 2 | 3 | 4 | 5 | 6 | 7 | 8 | 9 |
| initial | −2.6235 | −1.5613 | −0.1638 | 1.2351 | −0.5261 | 1.2577 | 2.4830 | 0.2584 | −2.0124 |
| threshold | | | | | | | | | |

| | |
|---|---|
| output | reaming torque |
| layer | |
| threshold | −1.8245 |

S8: Assigning optimized initial weights and initial thresholds in S7 to the neural network model in S6, and training it thought the training sample P. and then establishing a reaming torque BP neural network prediction model on the basis of an average influence value method and a genetic algorithm.

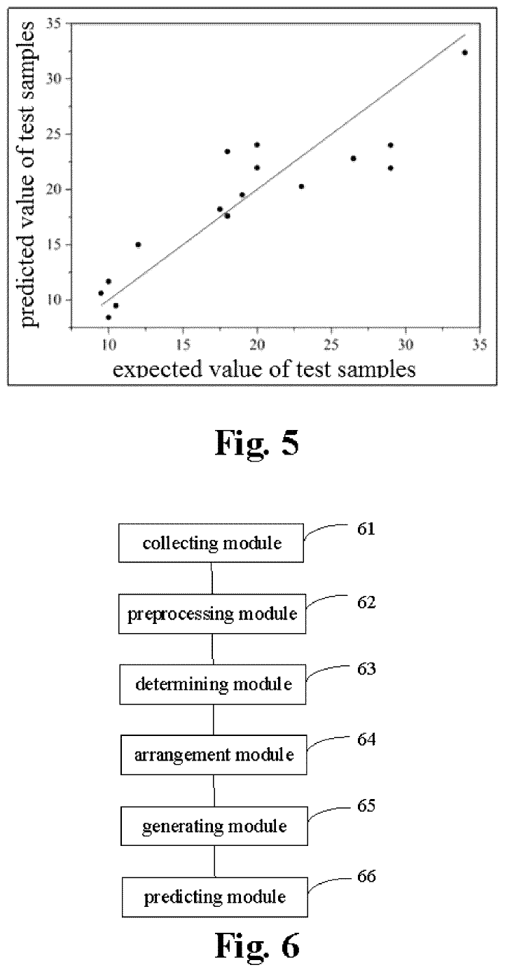

S9: Predicting the reaming torque of the test sample V by means of the prediction model established in S8 and comparing it with an expected value. The results are shown in FIG. 5.

### Example 2

As shown in FIG. 6, this example proposes an apparatus for predicting horizontal directional drilling-reaming torque, which includes:

A collecting module 61 used for collecting horizontal directional drilling data and initial reaming torque data corresponding to the horizontal directional drilling data.

Wherein, on the basis of an existing large amount of data about projects for horizontally directionally drilling and laying down pipelines, collecting the horizontal directional drilling data, which includes dragging-back force data (unit: kN), rotation rate data (unit: r/pm), dragging-back distance data (unit: m), drilling angle change data (unit: rad), reamed diameter data (unit: mm), mud pumping volume data (unit: L/min) and mud funnel viscosity data (unit: s) as well as the initial reaming torque data corresponding to the above horizontal directional drilling data, that is, reaming torque (unit: kN·m).

Further, performing conversion on the collected horizontal directional drilling data and the initial reaming torque data on the basis of the units of the above physical quantities, then establishing a dataset on the basis of the converted horizontal directional drilling data and initial reaming torque data, next randomly selecting part of the data in the dataset as training samples P, and using the remaining data in the dataset as test samples V.

Further, enabling the number of the training samples to account for about ⅘ of the total of the samples in the dataset, or determining the number by way of generating random integers in the range of (1, the total of the samples in the dataset).

A preprocessing module 62 used for preprocessing the horizontal directional drilling data to generate multiple reaming torque prediction data elements.

Specifically, determining a BP neural network structure (feedforward neural network structure), number of hidden layer neurons, a transfer function and an evaluation function and establishing an initial neural network model, then using the dragging-back force data, the rotation rate data, dragging-back distance data, the drilling angle change data, the reamed diameter data, the mud pumping volume data and the mud funnel viscosity data in the training sample P as input variables, and the initial reaming torque data as output variables, so as to train the initial neural network model.

Wherein, the initial neural network model adopts a three-layer BP neural network structure (that is, an input layer, a hidden layer and an output layer), a hidden layer transfer function adopts a hyperbolic tangent S-shaped function, an output layer transfer function adopts a linear function, and a mean square error is used as a network performance evaluation function, and the number of the hidden layer neurons is calculated by the following formula.

$$M = 2 N + 1$$

In the above formula, M represents number of hidden layer neurons, and N represents number of input variables.

Further, inputting the horizontal directional drilling data to which a preset value has been added (referring to the horizontal directional drilling data in the test sample P) and the horizontal directional drilling data from which a preset value has been removed, into an initial neural network model to generate multiple reaming torque prediction data elements; wherein the multiple reaming torque prediction data elements includes a reaming torque prediction data element corresponding to the horizontal directional drilling data to which a preset value has been added and a reaming torque prediction data element corresponding to the horizontal directional drilling data from which a preset value has been removed.

Wherein, the input variable in the training sample P (that is, the horizontal directional drilling data in the test sample P) increases by 10% on the basis of its original value to form a new training sample P1, and decreases by 10% on the basis of its original value to form a new training sample P2, thus P1 and P2 are input into the outputs corresponding to predicting P1 and P2 in the initial neural network model, which are A1 (that is, the reaming torque prediction data element corresponding to the horizontal directional drilling data to which a preset value has been added) and A2 (that is, the reaming torque prediction data element corresponding to the horizontal directional drilling data from which a preset value has been removed), respectively.

A determining module 63 used for determining an average influence parameter of the horizontal directional drilling data influencing on the reaming torque on the basis of the multiple reaming torque prediction data elements.

Wherein, the average influence parameter of the horizontal directional drilling data influencing on the reaming torque includes an average influence value, and the average influence value is calculated by the following formula.

$$MIV = \frac{{{\sum }^{n}}_{i = 1} ( A 1 - A 2 )}{n}$$

In the above formula, MIV represents an average influence value, n represents number of horizontal directional drilling data (that is, number of training samples), A1 represents a reaming torque prediction data element corresponding to the horizontal directional drilling data to which a preset value has been added, A2 represents a reaming torque prediction data element corresponding to the horizontal directional drilling data from which a preset value has been removed.

An arrangement module 64 used for screening the horizontal directional drilling data on the basis of the average influence parameters to obtain different drilling data combinations.

Wherein, sequencing the average influence parameters (that is, the average influence value corresponding to the horizontal directional drilling data in the test sample P) from a large one to a small one, and selecting the horizontal directional drilling data corresponding to the average influence parameters of different preset numbers (N≥3) on the basis of a sequenced result to make an arrangement and combination, so as to generate different drilling data combinations.

For example, sequencing the horizontal directional drilling data based on the result of sequencing the average influence values among the average influence parameters, and the result is as follows: dragging-back force data, rotation rate data, dragging-back distance data, drilling angle change data, reamed diameter data, mud pumping volume data, mud funnel viscosity data; selecting the top 3 horizontal directional drilling data as a first drilling data combination (dragging-back force data, rotation rate data, dragging-back distance data); selecting the top 4 horizontal directional drilling data as a second drilling data combination (dragging-back force data, rotation rate data, dragging-back distance data, drilling angle change data); selecting the top 5 horizontal directional drilling data as a third drilling data combination (dragging-back force data, rotation rate data, dragging-back distance data, drilling angle change data, reamed diameter data); selecting the top 6 horizontal directional drilling data as a fourth drilling data combination (dragging-back force data, rotation rate data, dragging-back distance data, drilling angle change data, reamed diameter data, mud pumping volume data); selecting the top 7 horizontal directional drilling data as a fifth drilling data combination (dragging-back force data, rotation rate data, dragging-back distance data, drilling angle change data, reamed diameter data, mud pumping volume data, mud funnel viscosity data); then, generating five sets of drilling data combinations, that is (dragging-back force data, rotation rate data, dragging-back distance data), (dragging-back force data, rotation rate data, dragging-back distance data, drilling angle change data), (dragging-back force data, rotation rate data, dragging-back distance data, drilling angle change data, reamed diameter data), (dragging-back force data, rotation rate data, dragging-back distance data, drilling angle change data, reamed diameter data, mud pumping volume data), (dragging-back force data, rotation rate data, dragging-back distance data, drilling angle change data, reamed diameter data, mud pumping volume data, mud funnel viscosity data).

A generating module 65 used for generating a linear fitting determination coefficient on the basis of the different drilling data combinations and the initial reaming torque data.

A predicting module 66 used for selecting a drilling data combination corresponding to a maximum linear fitting determination coefficient to establish a reaming torque predicting model, and using the reaming torque predicting model to predict horizontal directional drilling-reaming torque.

The above-mentioned method for predicting horizontal directional drilling-reaming torque uses the reaming torque predicting model to predict the horizontal directional drilling-reaming torque on the basis of the horizontal directional drilling data, so the method can effectively improve the accuracy of predicting reaming torque, and it is simple, convenient and effective to apply the method, so as to provide a data basis for designing number of steps for reaming and model selection of drilling machines.

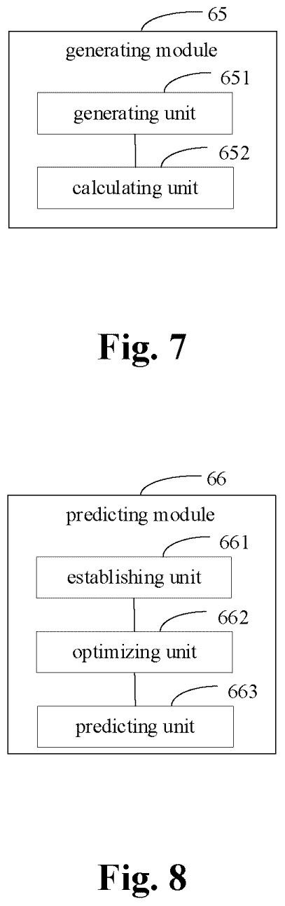

Preferably, as shown in FIG. 7, the generating module 65 includes:

A generating unit 651 used for establishing a neural network combination model on the basis of the different drilling data combinations, respectively, and using the neural network combination model to generate a reaming torque prediction data element corresponding to the different drilling data combinations.

Specifically, establishing the neural network combination models corresponding to the different drilling data combinations, respectively, wherein the BP neural network structure, the number of hidden layer neurons, the transfer function, the evaluation function and the output variables are the same as those of the initial neural network model, and the input variables are different drilling data combinations; using the data in the training sample P to train the combined neural network mode to generate a trained neural network combination model.

Furthermore, making an arrangement and combination on the horizontal directional drilling data in the test sample V according to the different drilling data combinations, and inputting the horizontal directional drilling data on which the arrangement and combination has been made, into the trained neural network combination model to generate the reaming torque prediction data element corresponding to the different drilling data combinations.

A calculating unit 652 used for generating a linear fitting determination coefficient on the basis of the reaming torque prediction data element corresponding to the different drilling data combinations and the initial reaming torque data.

Wherein, the linear fitting determination coefficient is calculated by the following formula.

$${R}^{2} = \frac{{\sum }_{i = 1}^{m} {( {y}_{i} - \frac{1}{m} {\sum }_{i = 1}^{m} {a}_{i} )}^{2}}{{\sum }_{i = 1}^{m} {( {a}_{i} - \frac{1}{m} {\sum }_{i = 1}^{m} {a}_{i} )}^{2}}$$

In the above formula, R² represents a linear fitting determination coefficient, m represents number of test samples, aᵢ represents an expected output of the i^{th} test sample (that is, initial reaming torque data in the test sample), yᵢ represents a predicted BP neural network output of the i^{th} test sample (that is, reaming torque prediction data element).

Preferably, as shown in FIG. 8, the predicting module 66 includes:

An establishing unit 661 used for selecting a drilling data combination corresponding to a maximum linear fitting determination coefficient as an optimal drilling data combination, and establishing an initial prediction model on the basis of the optimal drilling data combination.

Specifically, establishing an initial prediction model on the basis of the optimal drilling data combination, wherein the BP neural network structure, the number of hidden layer neurons, the transfer function, the evaluation function and the output variables are the same as those of the initial neural network model, and the input variable is the optimal drilling data combination; using the data in the training sample P to train the initial prediction model to generate a trained initial prediction model.

Alternatively, retrieving the neural network combination model corresponding to the optimal drilling data combination as a trained initial prediction model.

An optimizing unit 662 used for optimizing initial weights and thresholds of the initial prediction model, then assigning optimized initial weights and initial thresholds to the initial prediction model, so as to generate the horizontal directional drilling-reaming torque predicting model.

Specifically, determining initial parameters of a genetic algorithm, that is, setting an initial population size as 20, setting a population evolutionary generation number as 50, setting a crossover probability as 0.6, setting a mutation probability as 0.1, setting an initial weight range as (−3,3), and setting an initial threshold range as (−3,3); optimizing the initial weights and thresholds of the initial prediction model through the genetic algorithm.

Wherein, the step of optimizing the initial weights and thresholds of the initial prediction model through the genetic algorithm includes the following sub-steps.

(1) Population initialization: randomly generating a W-size initial population, in which each individual contains a set of weights and thresholds of the BP neural network.

(2) Individual coding: adopting a real number coding method to encode an individual into a real number string.

(3) Individual-fitness calculation: obtaining the weights and thresholds of the BP neural network after individual decoding, and training the BP neural network through the training sample P; obtaining a predicted output of the training sample P through the trained BP neural network, and taking a reciprocal of a squared error sum between the predicted output and an expected output of the training sample P as an individual fitness value F, which is calculated by the following formula.

$$F = \frac{1}{{\sum }_{i - 1}^{n} {( {y}_{i} - {a}_{i} )}^{2}}$$

In the formula, n represents number of training samples, aᵢ represents an expected output of the i^{th} test sample, yᵢ represents a predicted BP neural network output of the i^{th} test sample.

(4) Choice operation: using a proportional choice operator to calculate a probability that an individual is chosen; the probability Pᵢ that an individual i is chosen is as follows.

$${P}_{i} = \frac{{F}_{i}}{{{\sum }_{i = 1}}^{W} {F}_{i}}$$

In the formula, W represents number of individuals in a population; Fᵢ represents a fitness value of an individual i.

(5) Crossover operation: crossing an individual x with an individual y at a position j; a j-position gene at which they have been crossed with each other is calculated as the following formulas.

$${a}_{xi} = {a}_{xj} ( 1 - b ) + {a}_{yj} b$$

$${a}_{yj} = {a}_{yj} ( 1 - b ) + {a}_{xj} b$$

In the formulas, aₓⱼ represents a j-position gene at which an individual x has been crossed, a_{yj} represents a j-position gene at which an individual y has been crossed, b represents a random number in a range [0,1].

(6) Mutation operation: selecting a j-position gene of an individual x for mutation operation; the mutated j-position gene is as follows.

$${a}_{xj} = \{ \begin{matrix}{a}_{xj} + ( {a}_{xj} - {a}_{max} ) \cdot f ( g ) & r \leq 0.5 \\ {a}_{xj} + ( {a}_{xj} - {a}_{min} ) \cdot f ( g ) & r \geq 0.5\end{matrix}$$

$$f ( g ) = \frac{1}{{( 1 - g / {G}_{max} )}^{2}}$$

In the formulas, aₘₐₓ represents an upper limit of a j-position gene, aₘᵢₙ represents a lower limit of a j-position gene, g represents current number of iterations, Gₘₐₓ represents maximum number of iterations, r represents a random number in a range [0,1].

(7) Obtaining an optimal individual through the above steps (1)-(6), that is, an optimal initial weight and an optimal initial threshold of the BP neural network.

A predicting unit 663 used for collecting current horizontal directional drilling data, and inputting the current horizontal directional drilling data into the horizontal directional drilling-reaming torque predicting model so as to generate current reaming torque.

### Example 3

This example proposes a computer device, which includes a processor and a memory, the processor is used to read instructions stored in the memory to execute the method for predicting horizontal directional drilling-reaming torque mentioned in any above embodiments.

A person skilled in the art should understand that the examples of the present invention may be provided as a process, system, or computer program product. Therefore, the present invention may be embodied in a form of complete hardware, complete software, or a combination of software and hardware. In addition, the present invention may be embodied in a form of a computer program product executed on one or more computer-available storage media (including, but not limited to, a disk memory, a CD-ROM, an optical memory, etc.) containing computer-available program codes.

The present invention is described with reference to a flowchart and/or block diagram of a method, apparatus (system), and computer program product according to the examples of the present invention. It should be understood that computer program instructions can execute each process and/or block in the flowchart and/or block diagram, as well as a combination of the process and/or block in the flowchart and/or block diagram. These computer program instructions may be provided to processors of a general-purpose computer, a specialized computer, an embedded processing machine, or other programmable data processing devices to generate a machine, so that the instructions executed by the processors of the computer or other programmable data processing devices generates an apparatus used to achieve the functions specified in one or more processes of the flowchart and/or one or more blocks of the block diagram.

These computer program instructions may also be stored in a computer-readable memory capable of directing a computer or other programmable data-processing device to operate in a particular manner, so that the instructions stored in the computer-readable memory generate a manufactured product containing an instruction apparatus achieves the functions specified in one or more processes of the flowchart and/or one or more blocks of the block diagram.

These computer program instructions may also be loaded onto a computer or other programmable data processing devices, so that a series of operational steps are executed on the computer or other programmable devices to generate a process executed by the computer, so as to enable the instructions executed on the computer or other programmable devices to provide a step used to achieve the functions specified in one or more processes of the flowchart and/or one or more blocks of the block diagram.

### Example 4

This example provides a computer-readable storage medium, the computer storage medium stores a computer-executable instruction, and the computer-executable instruction can execute the method for predicting horizontal directional drilling-reaming torque mentioned in any above embodiments. Wherein, the storage medium may be a disk, an optical disk, a read-only memory (ROM), a random-access memory (RAM), a flash memory, a hard disk (HDD) or a solid-state drive (SSD); the storage medium may also include a combination of the above memories.

Obviously, the above examples are only used as instances to clearly describe the present invention and not pose any limitations on the embodiments. A person skilled in the art can make other changes or modification on the basis of the above description, but he/she has no need and no ability to enumerate all embodiments. Therefore, the obvious changes or modifications derived therefrom still fall within the protection scope of the present invention.

1. A method for predicting horizontal directional drilling-reaming torque, comprising the steps of
collecting horizontal directional drilling data and initial reaming torque data corresponding to the horizontal directional drilling data;
preprocessing the horizontal directional drilling data to generate multiple reaming torque prediction data elements;
determining an average influence parameter of the horizontal directional drilling data influencing on a reaming torque on a basis of the multiple reaming torque prediction data elements;
screening the horizontal directional drilling data on a basis of the average influence parameters to obtain different drilling data combinations;
generating a linear fitting determination coefficient on a basis of the different drilling data combinations and the initial reaming torque data; and
selecting a drilling data combination corresponding to a maximum linear fitting determination coefficient to establish a reaming torque predicting model, and using the reaming torque predicting model to predict horizontal directional drilling-reaming torque.

2. The method for predicting horizontal directional drilling-reaming torque according to claim 1, wherein the horizontal directional drilling data comprises dragging-back force data, rotation rate data, dragging-back distance data, drilling angle change data, reamed diameter data, mud pumping volume data and mud funnel viscosity data.

3. The method for predicting horizontal directional drilling-reaming torque according to claim 2, wherein the step of preprocessing the horizontal directional drilling data to generate multiple reaming torque prediction data elements comprises:
inputting the horizontal directional drilling data to which a preset value was added and the horizontal directional drilling data from which a preset value was removed, into an initial neural network model to generate multiple reaming torque prediction data elements;
wherein, the multiple reaming torque prediction data elements includes a reaming torque prediction data element corresponding to the horizontal directional drilling data to which the preset value was added and a reaming torque prediction data element corresponding to the horizontal directional drilling data from which the preset value was removed.

4. The method for predicting horizontal directional drilling-reaming torque according to claim 3, wherein the average influence parameter of the horizontal directional drilling data influencing on the reaming torque comprises an average influence value, and the average influence value is calculated by the following formula,
$$MIV = \frac{{{\sum }^{n}}_{i = 1} ( A 1 - A 2 )}{n}$$
where MIV represents an average influence value, n represents number of horizontal directional drilling data, A1 represents the reaming torque prediction data element corresponding to the horizontal directional drilling data to which the preset value was added, A2 represents the reaming torque prediction data element corresponding to the horizontal directional drilling data from which the preset value was removed.

5. The method for predicting horizontal directional drilling-reaming torque according to claim 1, wherein the step of screening the horizontal directional drilling data on the basis of the average influence parameters to obtain different drilling data combinations comprises:
sequencing the average influence parameters from a large one to a small one, and selecting the horizontal directional drilling data corresponding to the average influence parameters of different preset numbers on a basis of a sequenced result to make an arrangement and combination, so as to generate different drilling data combinations.

6. The method for predicting horizontal directional drilling-reaming torque according to claim 1, wherein the step of generating a linear fitting determination coefficient on the basis of the different drilling data combinations and the initial reaming torque data comprises:
establishing a neural network combination model on a basis of the different drilling data combinations, respectively, and using the neural network combination model to generate a reaming torque prediction data element corresponding to the different drilling data combinations; and
generating a linear fitting determination coefficient on the basis of the reaming torque prediction data element corresponding to the different drilling data combinations and the initial reaming torque data.

7. The method for predicting horizontal directional drilling-reaming torque according to claim 1, wherein the step of selecting a drilling data combination corresponding to a maximum linear fitting determination coefficient to establish a reaming torque predicting model, and using the reaming torque predicting model to predict horizontal directional drilling-reaming torque comprises:
selecting a drilling data combination corresponding to a maximum linear fitting determination coefficient as an optimal drilling data combination, and establishing an initial prediction model on the basis of the optimal drilling data combination;
optimizing initial weights and thresholds of the initial prediction model, then assigning optimized initial weights and initial thresholds to the initial prediction model, so as to generate the horizontal directional drilling-reaming torque predicting model; and
collecting current horizontal directional drilling data, and inputting the current horizontal directional drilling data into the horizontal directional drilling-reaming torque predicting model so as to generate current reaming torque.

8. An apparatus for predicting horizontal directional drilling-reaming torque, comprising:
a collecting module used for collecting horizontal directional drilling data and initial reaming torque data corresponding to the horizontal directional drilling data;
a preprocessing module used for preprocessing the horizontal directional drilling data to generate multiple reaming torque prediction data elements;
a determining module used for determining an average influence parameter of the horizontal directional drilling data influencing on the reaming torque on the basis of the multiple reaming torque prediction data elements;
an arrangement module used for screening the horizontal directional drilling data on the basis of the average influence parameters to obtain different drilling data combinations;
a generating module used for generating a linear fitting determination coefficient on the basis of the different drilling data combinations and the initial reaming torque data; and
a predicting module used for selecting a drilling data combination corresponding to a maximum linear fitting determination coefficient to establish a reaming torque predicting model, and using the reaming torque predicting model to predict horizontal directional drilling-reaming torque.

9-10. (canceled)
